(19) United States
(12) Patent Application Publication
(10) Pub. No.: US 2024/0429146 A1
(43) Pub. Date: Dec. 26, 2024

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Minwoo Cho, Suwon-si (KR); Hyunggil Baek, Suwon-si (KR); Shlege Lee, Suwon-si (KR)

(21) Appl. No.: 18/639,148

(22) Filed: Apr. 18, 2024

(30) Foreign Application Priority Data
Jun. 26, 2023 (KR) 10-2023-0082037

(51) Int. Cl. H01L 23/498; H01L 23/00; H01L 25/065

(52) U.S. Cl. CPC H01L 23/49816; H01L 23/49822; H01L 24/08; H01L 24/16; H01L 25/0652; H01L 2224/08137; H01L 2224/08155; H01L 2224/16146; H01L 2224/16227; H01L 2924/0665; H01L 2924/1431; H01L 2924/1434; H01L 2924/15311; H01L 2924/18161

(57) ABSTRACT

A semiconductor package includes a lower substrate that includes a chip mounting region and a peripheral region, where the lower substrate includes lower redistribution wirings; a first semiconductor chip on the chip mounting region, where the first semiconductor chip includes: a silicon substrate that includes a first surface and a second surface that are opposite to each other, an activation layer on the second surface, and a chip redistribution wiring layer that is on the first surface and includes a plurality of chip redistribution wirings that are electrically insulated from the activation layer; a plurality of connecting members that are on the peripheral region and are electrically connected to the lower redistribution wirings; and an upper substrate on the plurality of connecting members, and where at least a portion of the first semiconductor chip is in a through cavity defined by the upper substrate.

### PRIORITY STATEMENT

This application claims priority under 35 U.S.C. § 119 to Korean Patent Application No. 10-2023-0082037, filed on Jun. 26, 2023 in the Korean Intellectual Property Office (KIPO), the contents of which are herein incorporated by reference in their entirety.

### TECHNICAL FIELD

Example embodiments relate to a semiconductor package and a method of manufacturing the semiconductor package. More particularly, example embodiments relate to a semiconductor package including a plurality of different semiconductor chips stacked on one another and a method of manufacturing the same.

### BACKGROUND

In a semiconductor package having a plurality of semiconductor chips stacked on one another, thermal characteristics may be improved to thereby improve an overall performance of the semiconductor package. As an example, a method of increasing thicknesses of the semiconductor chips may be used to reduce a thermal resistance in order to improve the thermal characteristics. In a semiconductor device that has a preset thickness, the thickness of the semiconductor chip may be thinned by decreasing a thickness of an interposer substrate and a mold gap that is a spacing distance between the interposer substrate and the semiconductor chip. However, as the thickness of the semiconductor chip becomes thinner, there is a problem in that the thermal characteristics deteriorate.

### SUMMARY

Example embodiments provide a semiconductor package having a structure capable of improving heat characteristics.

Example embodiments provide a method of manufacturing the semiconductor package.

According to example embodiments, a semiconductor package includes a lower substrate that includes a chip mounting region and a peripheral region that at least partially surrounds the chip mounting region, where the lower substrate includes lower redistribution wirings; a first semiconductor chip on the chip mounting region, where the first semiconductor chip includes: a silicon substrate that includes a first surface and a second surface that are opposite to each other, an activation layer on the second surface, and a chip redistribution wiring layer that is on the first surface and includes a plurality of chip redistribution wirings that are electrically insulated from the activation layer; a plurality of connecting members that are on the peripheral region and are electrically connected to the lower redistribution wirings; and an upper substrate on the plurality of connecting members, where the upper substrate includes upper wirings that are electrically connected to the plurality of connecting members, where the upper substrate defines a through cavity that is on the chip mounting region, and where at least a portion of the first semiconductor chip is in the through cavity.

According to example embodiments, a semiconductor package includes a lower substrate that includes a chip mounting region and a peripheral region that at least partially surrounds the chip mounting region, where the lower substrate includes lower redistribution wirings; a first semiconductor chip on the chip mounting region, where the first semiconductor chip includes: a silicon substrate that includes a first surface and a second surface that are opposite to each other, an activation layer on the second surface, and a chip redistribution wiring layer that is on the first surface and includes a plurality of chip redistribution wirings that are electrically insulated from the activation layer; a sealing member that is on the lower substrate and overlaps an outer surface of the first semiconductor chip; a plurality of connecting members that are on the peripheral region, where the plurality of connecting members extend into the sealing member and are electrically connected to the lower redistribution wirings; and an upper substrate that is on the sealing member and includes upper wirings, where the upper substrate is electrically connected to the plurality of connecting members by the upper wirings, and where the upper substrate defines a through cavity that is on the chip mounting region and receives at least a portion of the first semiconductor chip.

According to example embodiments, a semiconductor package includes a lower substrate that includes a chip mounting region and a peripheral region that at least partially surrounds the chip mounting region, where the lower substrate includes lower redistribution wirings; a first semiconductor chip on the chip mounting region, where the first semiconductor chip includes: a silicon substrate that includes a first surface and a second surface that are opposite to each other, an activation layer that is on the second surface and is electrically connected to the lower redistribution wirings, and a chip redistribution wiring layer that is on the first surface and includes a plurality of chip redistribution wirings that are electrically insulated from the activation layer; a sealing member that is on the lower substrate and overlaps an outer surface of the first semiconductor chip; a plurality of connecting members that are on the peripheral region, where the plurality of connecting members extend into the sealing member and are electrically connected to the lower redistribution wirings; an upper substrate that is on the sealing member and includes upper wirings, where the upper substrate is electrically connected to the plurality of connecting members by the upper wirings, where the upper substrate defines a through cavity that is on the chip mounting region, and where least a portion of the first semiconductor chip is in the through cavity; and a semiconductor device that is on the upper substrate and is electrically connected to the upper wirings of the upper substrate and the chip redistribution wirings of the first semiconductor chip.

According to example embodiments, a semiconductor package may include a lower substrate having a chip mounting region and a peripheral region surrounding the chip mounting region, and having lower redistribution wirings, a first semiconductor chip mounted on the chip mounting region, and including a silicon substrate having a first surface and a second surface opposite to each other, an activation layer provided on the second surface, and a chip redistribution wiring layer provided on the first surface and having a plurality of chip redistribution wirings electrically insulated from the activation layer, a plurality of connecting members provided on the peripheral region on the lower substrate and electrically connected to the lower redistribution wirings, and an upper substrate disposed on the plurality of connecting members, having upper wirings that are electrically connected to the plurality of connecting members, and having a through cavity that is provided on the chip mounting region and accommodates at least a portion of the first semiconductor chip.

Accordingly, the first semiconductor chip may transfer heat generated from the activation layer to the first surface of the silicon substrate. The chip redistribution wiring layer may absorb the heat and dissipate it upward. Because the upper substrate accommodates the first semiconductor chip in the through cavity, the overall thickness of the semiconductor package may be maintained and the thickness of the silicon substrate may be increased. Because the thickness of the silicon substrate increases, the thermal characteristics of the semiconductor package may be improved.

A semiconductor device may be mounted on an upper surface of the chip redistribution wiring layer and the upper substrate. Since the chip redistribution wiring layer mounts the semiconductor device on the upper surface thereof, a mold gap between the first semiconductor chip and the upper substrate may be reduced. The first semiconductor chip may directly transfer the heat generated from the activation layer to the semiconductor device through the chip redistribution wiring layer. Since the first semiconductor chip is accommodated in the through cavity, the heat spreading effect may be improved.

Further, the chip redistribution wiring layer of the first semiconductor chip may be electrically insulated from the activation layer. The chip redistribution wiring layer may be electrically connected to the semiconductor device mounted on the upper substrate. Since the chip redistribution wiring layer is electrically insulated from the activation layer, heat may not be generated within the chip redistribution wiring layer and the chip redistribution wiring layer may only absorb the heat from the activation layer through the silicon substrate.

### BRIEF DESCRIPTION OF THE DRAWINGS

Example embodiments will be more clearly understood from the following detailed description taken in conjunction with the accompanying drawings. FIGS. 1 to 12 represent non-limiting, example embodiments as described herein.

FIG. 1 is a plan view illustrating a semiconductor package in accordance with example embodiments of the present disclosure.

FIG. 2 is a cross-sectional view taken along the line A-A′ in FIG. 1.

FIG. 3 is a plan view illustrating an upper substrate and a first semiconductor chip of FIG. 2.

FIG. 4 is an enlarged cross-sectional view illustrating portion ‘B’ in FIG. 2.

FIGS. 5, 6, 7, 8, 9, and 10 are views illustrating a method of manufacturing a semiconductor package in accordance with example embodiments of the present disclosure.

FIG. 11 is a cross-sectional view illustrating a semiconductor package in accordance with example embodiments of the present disclosure.

FIG. 12 is a cross-sectional view illustrating a semiconductor package in accordance with example embodiments of the present disclosure.

### DETAILED DESCRIPTION OF EXAMPLE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

Hereinafter, example embodiments will be explained in detail with reference to the accompanying drawings.

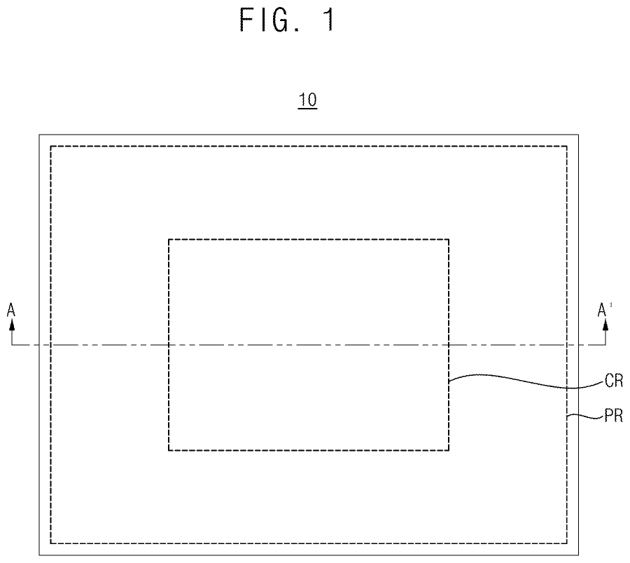

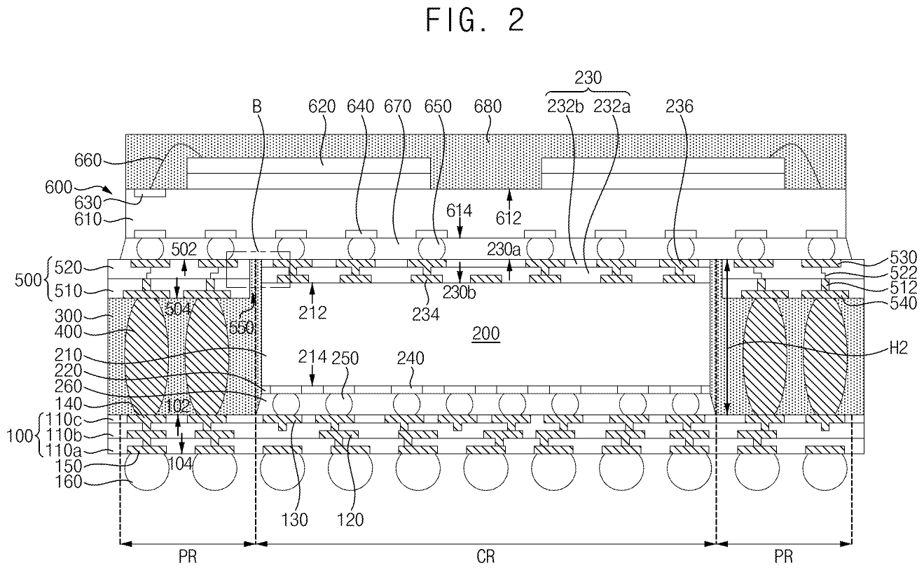

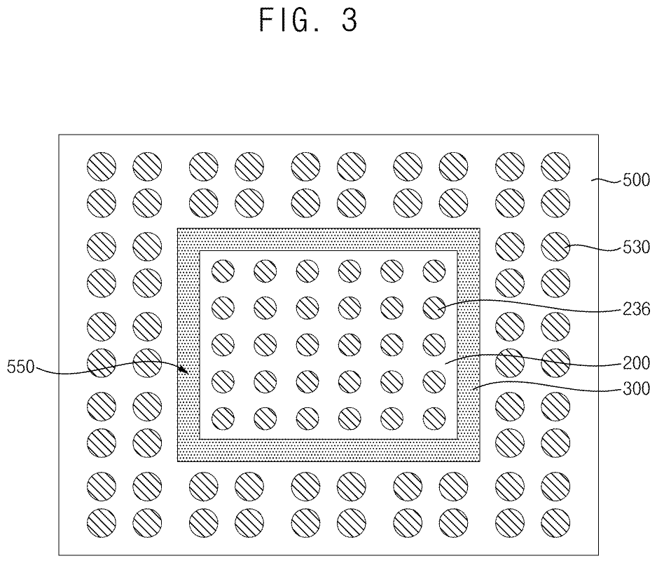

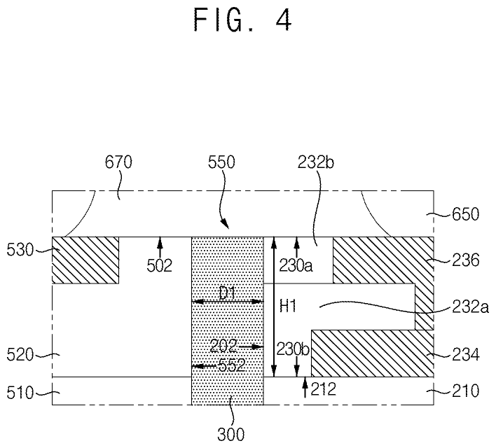

FIG. 1 is a plan view illustrating a semiconductor package in accordance with example embodiments of the present disclosure. FIG. 2 is a cross-sectional view taken along the line A-A′ in FIG. 1. FIG. 3 is a plan view illustrating an upper substrate and a first semiconductor chip of FIG. 2. FIG. 4 is an enlarged cross-sectional view illustrating portion ‘B’ in FIG. 2.

Referring to FIGS. 1 to 4, a semiconductor package 10 may include a lower substrate 100, at least one first semiconductor chip 200 mounted on the lower substrate 100, a first sealing member 300 covering or overlapping the at least one first semiconductor chip 200 on the lower substrate 100, a plurality of connecting members 400 extending into the first sealing member 300 and in a vertical direction, and an upper substrate 500 disposed on the first sealing member 300 and having a through cavity 550. The semiconductor package 10 may further include at least one semiconductor device 600 mounted on the upper substrate 500.

In example embodiments, the semiconductor package 10 may be a memory module having a stacked chip structure in which a plurality of dies (chips) are stacked. For example, the first semiconductor chip 200 may be a processor chip, such as an ASIC or an application processor (AP) operating as a host, such as a CPU, GPU, or SOC. The semiconductor device 600 may include a high bandwidth memory (HBM) device, dynamic random access memory (DRAM), etc.

In example embodiments, the lower substrate 100 may include a first upper surface 102 and a first lower surface 104 that are opposite to each other. For example, the lower substrate 100 may include a printed circuit board (PCB). The lower substrate 100 may include a redistribution wiring layer. The lower substrate 100 may be a multilayer circuit board having vias and various circuits therein.

The lower substrate 100 may include a plurality of lower redistribution wirings 120. The lower substrate 100 may include a plurality of first and second bonding pads 130 and 140 that are exposed at an upper surface of the lower substrate 100 (that is, the first upper surface 102), and a plurality of first connection pads 150 exposed at a lower surface (that is, the first lower surface 104 of the lower substrate 100).

The lower substrate 100 may include a chip mounting region CR on which the first semiconductor chip 200 is mounted and a peripheral region PR at least partially surrounding the chip mounting region CR. The first bonding pads 130 on which the first semiconductor chip 200 is mounted may be provided in the chip mounting region CR. The second bonding pads 140 on which the connecting members 400 are disposed may be provided in the peripheral region PR.

In example embodiments, the lower substrate 100 may include a plurality of lower insulating layers 110a, 110b, 110c and the lower redistribution wirings 120 provided in the lower insulating layers 110a, 110b, 110c. The lower insulating layers 110a, 110b, 110c may include a polymer, a dielectric layer, etc. The lower insulating layers 110a, 110b, 110c may be formed by a vapor deposition process, a spin coating process, etc. The lower redistribution wirings 120 may be formed by a plating process, an electroless plating process, a vapor deposition process, etc. The lower redistribution wirings 120 may electrically connect the first and second bonding pads 130 and 140 and the first connection pads 150.

In example embodiments, the lower insulating layers 110a, 110b, 110c may cover or overlap the lower redistribution wirings 120. A first insulating layer (e.g., a lowermost insulating layer) 110a may be provided in the first lower surface 104 of the lower substrate 100, and a third insulating layer (e.g., an uppermost insulating layer) 110c may be provided in the first upper surface 102 of the lower substrate 100.

In particular, the plurality of first and second bonding pads 130 and 140 may be provided in the third insulating layer 110c. Upper surfaces of the first and second bonding pads 130 and 140 may be exposed at an upper surface of the third insulating layer 110c, (that is, the first upper surface 102). The third insulating layer 110c may have third openings that expose upper surfaces of the first and second bonding pads 130 and 140.

The plurality of first connection pads 150 may be provided in the first insulating layer 110a. Lower surfaces of the first connection pads 150 may be exposed at a lower surface of the first insulating layer 110a, (that is, the first lower surface 104). The first insulating layer 110a may have first openings that expose lower surfaces of the first connection pads 150.

The lower redistribution wirings 120 may be formed on the first insulating layer 110a and may contact the first connection pads 150 through the first openings. A second insulating layer 110b may be formed on the first insulating layer 110a and may have second openings that expose the lower redistribution wirings 120.

The first and second bonding pads 130 and 140 may be formed on the second insulating layer 110b and may contact the lower redistribution wirings 120 through the second openings. The third insulating layer 110c may be formed on the second insulating layer 110b and may expose the first and second bonding pads 130 and 140 through third openings. Accordingly, the plurality of first and second bonding pads 130 and 140 may be exposed at the upper surface of the third insulating layer 110c, (that is, the first upper surface 102).

For example, the first and second bonding pads 130 and 140, the first connection pad 150, and the lower redistribution wirings 120 may include nickel (Ni), antimony (Sb), bismuth (Bi), Zinc (Zn), indium (In), palladium (Pd), platinum (Pt), aluminum (Al), copper (Cu), molybdenum (Mo), titanium (Ti), gold (Au), silver (Ag), chromium (Cr), tin (Sn), or an alloy thereof.

In example embodiments, the lower substrate 100 may be connected to other semiconductor devices through external connection bumps 160 that serve as conductive connecting members. The external connection bumps 160 may be provided on the first connection pads 150 respectively. For example, the external connection bump 160 may include a C4 bump.

In example embodiments, the first semiconductor chip 200 may include a silicon substrate 210 having a first surface 212 and a second surface 214 that are opposite to each other, an activation layer 220 provided on the second surface 214, and a chip redistribution wiring layer 230. For example, the silicon substrate 210 may include a semiconductor material, such as silicon, germanium, silicon-germanium, etc., or a group III-V compound semiconductor, such as gallium phosphide (GaP), gallium arsenide (GaAs), gallium antimonide (GaSb), etc.

The activation layer 220 (e.g., an active layer) may include circuit patterns. The activation layer 220 may be provided on the second surface 214 of the silicon substrate 210. The circuit patterns may include transistors, diodes, etc. The circuit patterns may constitute circuit elements. Accordingly, the first semiconductor chip 200 may have a plurality of circuit elements therein. The circuit pattern may include active elements or passive elements. The circuit pattern may include a transistor, diode, etc. The circuit pattern may be formed through a wafer process called front-end-of-line (FEOL).

The activation layer 220 may be electrically connected to the lower redistribution wirings 120 of the lower substrate 100. The activation layer 220 may include a wiring layer electrically connected to the circuit patterns. The wiring layer may be formed on the second surface 214 of the silicon substrate 210 by a wiring process called back-end-of-line (BEOL). The wiring layer may have wirings therein. For example, the wirings may include aluminum (Al), copper (Cu), tin (Sn), nickel (Ni), gold (Au), platinum (Pt), or an alloy thereof.

In example embodiments, the chip redistribution wiring layer 230 may be provided on the first surface 212 of the silicon substrate 210. The chip redistribution wiring layer 230 may have a second upper surface 230a and a second lower surface 230b that are opposite to each other. The chip redistribution wiring layer 230 may include a plurality of chip insulating layers 232a, 232b, a plurality of chip redistribution wirings 234 provided in the chip insulating layers, and a plurality of chip redistribution pads 236 electrically connected to the chip redistribution wirings 234. The chip insulating layers 232a, 232b may include a polymer, a dielectric layer, etc. The chip insulating layers 232a, 232b may be formed by a vapor deposition process, a spin coating process, etc. The chip redistribution wirings 234 and the chip redistribution pads 236 may be formed by a plating process, an electroless plating process, a vapor deposition process, etc.

In example embodiments, a first chip insulating layer 232a may be provided on the first surface 212 of the silicon substrate 210 to cover or overlap the chip redistribution wirings 234, and a second chip insulating layer 232b may be provided on the chip insulating layer 232a.

In particular, at least portions of the chip redistribution wirings 234 may be exposed at an upper surface of the first chip insulating layer 232a. The first chip insulating layer 232a may have seventh openings that expose at least portions of the chip redistribution wirings 234.

The chip redistribution pads 236 may be formed on the first chip insulating layer 232a and may contact the chip redistribution pads 236 through the seventh openings. The second chip insulating layer 232b may be formed on the first chip insulating layer 232a and may have eighth openings that expose the chip redistribution pads 236. Accordingly, the plurality of chip redistribution pads 236 may be provided to be exposed at an upper surface of the second chip insulating layer 232b, (that is, the second upper surface 230a).

For example, the chip redistribution wirings 234 and the chip redistribution pads 236 may include nickel (Ni), antimony (Sb), bismuth (Bi), zinc (Zn), indium (In), and palladium (Pd), platinum (Pt), aluminum (Al), copper (Cu), molybdenum (Mo), titanium (Ti), gold (Au), silver (Ag), chromium (Cr), tin (Sn), or an alloy thereof.

The chip redistribution wiring layer 230 of the first semiconductor chip 200 may have a first height H1 from the first surface 212 of the silicon substrate 210. The chip redistribution wiring layer 230 of the first semiconductor chip 200 may absorb heat generated from the activation layer 220 through the silicon substrate 210. The first height H1 of the first semiconductor chip 200 may be determined based on the heat generated from the activation layer 220.

For example, when the heat generated from the activation layer 220 increases, the first height H1 of the chip redistribution wiring layer 230 may decrease. When the first height H1 decreases, a thickness of the silicon substrate 210 may increase. Accordingly, a capacity of the silicon substrate 210 to accommodate the heat may increase. The first height H1 may be within a range of about 25 μm to about 35 μm.

In example embodiments, the first semiconductor chip 200 may be disposed on the lower substrate 100. The first semiconductor chip 200 may be disposed on the lower substrate 100 such that the second surface 214 of the silicon substrate 210 faces the lower substrate 100. The first semiconductor chip 200 may be mounted on the chip mounting region CR of the lower substrate 100.

The first semiconductor chip 200 may be mounted on the lower substrate 100 using a flip chip bonding method. In this case, the first semiconductor chip 200 may be mounted on the lower substrate 100 such that the activation layer 220 on which first chip pads 240 are formed faces the lower substrate 100. The first chip pads 240 of the first semiconductor chip 200 may be electrically connected to the first bonding pads 130 of the lower substrate 100 by first solder bumps 250 as conductive connecting members. For example, the first solder bump 250 may include a micro bump (uBump).

A first adhesive member 260 may be provided between the first semiconductor chip 200 and the lower substrate 100. For example, the first adhesive member 260 may include an epoxy material.

In example embodiments, the first sealing member 300 may cover or overlap the first semiconductor chip 200 and the connecting members 400 on the lower substrate 100. The first sealing member 300 may be provided on the lower substrate 100 to be in the space between the lower substrate 100 and the upper substrate 500.

The first sealing member 300 may cover or overlap an outer surface 202 of the first semiconductor chip 200 on the lower substrate 100. The second upper surface 230a of the chip redistribution wiring layer 230 may be exposed at the first sealing member 300. The first sealing member 300 may cover or overlap an inner wall 552 of the through cavity 550 of the upper substrate 500.

The first sealing member 300 may include a plurality of through openings in which the connecting members 400 are provided. Within the through opening, one end portion of the connecting member 400 may be electrically connected to the second bonding pad 140 of the lower substrate 100, and the other end portion of the connecting member 400 may be electrically connected to a second connection pad 540 of the upper substrate 500.

The upper substrate 500 may be disposed on an upper surface of the first sealing member 300. The semiconductor device 600 may be in direct contact with the first semiconductor chip 200, and the first sealing member 300 may not be provided between the first semiconductor chip 200 and the semiconductor device 600. Since the first sealing member 300 is not provided between the first semiconductor chip 200 and the semiconductor device 600, the first sealing member 300 may not interfere with heat transfer between the first semiconductor chip 200 and the semiconductor device 600.

For example, the first sealing member 300 may include an epoxy mold compound (EMC). The first sealing member 300 may include UV resin, polyurethane resin, silicone resin, silica filler, etc.

In example embodiments, the connecting members 400 may be provided within the first sealing member 300 to electrically connect the lower substrate 100 and the upper substrate 500. The connecting members 400 may be provided in the through openings of the first sealing member 300. The connecting members 400 may extend from the lower substrate 100 in a vertical direction, (that is, a thickness direction of the lower substrate 100).

The connecting members 400 may be provided on the lower substrate 100. The connecting members 400 may be provided on the peripheral region PR surrounding the chip mounting region CR. The connecting members 400 may be provided outside the first semiconductor chip 200 mounted in the chip mounting region CR.

In particular, the connecting members 400 may be electrically connected to the lower redistribution wirings 120. The connecting members 400 may be electrically connected to the second bonding pads 140 of the lower substrate 100. The connecting members 400 may provide signal movement paths for electrically connecting the upper substrate 500 and the lower substrate 100.

For example, the connecting members 400 may include pillars, bumps, etc. Each of the connecting members 400 may include a copper pillar and a solder bump. The connecting members 400 may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), tin (Sn), or an alloy thereof. The connecting members 400 may be formed by a plating process, an electroless plating process, a vapor deposition process, etc.

In example embodiments, the upper substrate 500 may have a third upper surface 502 and a third lower surface 504 that are opposite to each other. The upper substrate 500 may include a silicon interposer. The upper substrate 500 may include a semiconductor substrate 510 and a wiring layer 520 on an upper surface of the semiconductor substrate 510 and having a plurality of redistribution wirings 522 and third bonding pads 530. The third bonding pads 530 may be exposed at the third upper surface 502 of the upper substrate 500.

The semiconductor substrate 510 may include a plurality of through electrodes 512 formed therein and a plurality of second connection pads 540 electrically connected to the plurality of through electrodes 512. The second connection pads 540 may be exposed at the third lower surface 504 of the upper substrate 500.

The through electrode 512 may include a through silicon via (TSV). The through electrode 512 may be provided to vertically extend into the semiconductor substrate 510. A first end portion of the through electrode 512 may be electrically connected to the redistribution wirings 522 of the wiring layer 520. A second end portion of the through electrode 512 opposite to the first end portion may be electrically connected to the second connection pad 540.

The upper substrate 500 may be disposed on the first sealing member 300. The upper substrate 500 may be disposed on the connecting members 400. At least one semiconductor device 600 may be disposed on the upper substrate 500. The third bonding pads 530 and the second connection pads 540 may be provided on the peripheral region PR.

The upper substrate 500 may have the through cavity 550 to accommodate at least a portion of the first semiconductor chip 200. The through cavity 550 may be provided on the chip mounting region CR of the lower substrate 100. The portion(s) of the first semiconductor chip 200 may be in the through cavity 550. The chip redistribution wiring layer 230 of the first semiconductor chip 200 may be in the through cavity 550. The first sealing member 300 may be provided between the inner wall 552 of the through cavity 550 and the outer surface 202 of the first semiconductor chip 200.

The outer surface 202 of the first semiconductor chip 200 may be spaced apart from the inner wall 552 of the through cavity 550. The inner wall 552 of the through cavity 550 and the outer surface 202 of the first semiconductor chip 200 may be spaced apart from each other by a first distance D1. Since the outer surface 202 of the first semiconductor chip 200 is spaced from the inner wall 552 of the through cavity 550, heat transfer between the upper substrate 500 and the first semiconductor chip 200 may be limited. Accordingly, the heat generated from the first semiconductor chip 200 may be transferred to the semiconductor device 600. For example, the first distance D1 may be within a range of about 1 mm to about 2 mm.

Because the first semiconductor chip 200 is in the through cavity 550, the occupying volume of the first sealing member 300 between the first semiconductor chip 200 and the upper substrate 500 may be reduced. Because the occupying volume of the first sealing member 300 is reduced, the first height H1 of the first semiconductor chip 200 may be increased. Because the first height H1 of the first semiconductor chip 200 increases, the thickness of the silicon substrate 210 may increase.

The second connection pads 540 may be electrically connected to the connecting members 400. The upper substrate 500 may be electrically connected to the lower substrate 100 through the connecting members 400 that are electrically connected to the second connection pads 540. The connecting members 400 may extend into the first sealing member 300 to electrically connect the upper substrate 500 and the lower substrate 100.

The third upper surface 502 of the upper substrate 500 and the second upper surface 230a of the chip redistribution wiring layer 230 may be provided on the same plane (i.e., the upper surfaces 502 and 230a are coplanar). Since the third upper surface 502 of the upper substrate 500 and the second upper surface 230a of the chip redistribution wiring layer 230 are provided on the same plane, the semiconductor device 600 may be stably disposed on the third upper surface 502 of the upper substrate 500 and the second upper surface 230a of the chip redistribution wiring layer 230 on the same plane.

The third upper surface 502 of the upper substrate 500 and the second upper surface 230a of the chip redistribution wiring layer 230 may have a second height H2 from the first upper surface 102 of the lower substrate 100. The second height H2 may be equal to a height of the first semiconductor chip 200. The second height H2 of the first semiconductor chip 200 may be increased through the chip redistribution wiring layer 230. By the chip redistribution wiring layer 230, the thickness of the silicon substrate 210 of the first semiconductor chip 200 may be increased, and thermal dissipation characteristics may be improved. For example, the second height H2 may be within a range of 180 μm to 220 μm.

In example embodiments, the semiconductor device 600 may be disposed on the upper substrate 500. The semiconductor device 600 may be disposed on the chip redistribution wiring layer 230 of the first semiconductor chip 200. The semiconductor device 600 may be disposed on the third upper surface 502 of the upper substrate 500 and the second upper surface 230a of the chip redistribution wiring layer 230. The semiconductor device 600 may include a substrate 610 and at least one second semiconductor chip 620 disposed on the substrate 610.

The substrate 610 of the semiconductor device 600 may include a third surface 612 and a fourth surface 614 opposite to each other. The substrate 610 may include first substrate pads 630 exposed at the third surface 612 and second substrate pads 640 exposed at the fourth surface 614. The substrate 610 may include second solder bumps 650 that are provided on the second substrate pads 640 respectively.

The second semiconductor chip 620 may be mounted on the substrate 610 using a wire bonding method. The second semiconductor chip 620 may be electrically connected to the first substrate pads 630 of the substrate 610 through conductive wires 660 that serve as conductive connecting members. Alternatively, the second semiconductor chip 620 may be mounted on the substrate 610 using a flip chip bonding method.

In another embodiment, the second semiconductor chip 620 may be disposed directly on the upper substrate 500 and the chip redistribution wiring layer 230. The second semiconductor chip 620 may be disposed on the third upper surface 502 of the upper substrate 500 and the second upper surface 230a of the chip redistribution wiring layer 230. For example, the second semiconductor chip 620 may include a semiconductor device such as a memory device. The second semiconductor chip 620 includes volatile memory devices, such as DRAM devices, SRAM devices, or non-volatile memory devices such as flash memory devices, PRAM devices, MRAM devices, ReRAM devices, or the like.

A second adhesive member 670 may be provided between the semiconductor device 600 and the upper substrate 500. The second adhesive member 670 may be provided between the semiconductor device 600 and the chip redistribution wiring layer 230. For example, the second adhesive member 670 may include an epoxy material.

The semiconductor device 600 may further include a second sealing member 680 that covers or overlaps the second semiconductor chip 620 on the substrate 610. For example, the second sealing member 680 may include an epoxy mold compound (EMC).

As mentioned above, the first semiconductor chip 200 may transfer heat generated from the activation layer 220 to the first surface 212 of the silicon substrate 210. The chip redistribution wiring layer 230 may absorb the heat and dissipate it upward. Because the upper substrate 500 accommodates the first semiconductor chip 200 in the through cavity 550, the overall thickness of the semiconductor package 10 may be maintained and the thickness of the silicon substrate 210 may be increased. Because the thickness of the silicon substrate 210 increases, the thermal dissipation characteristics of the semiconductor package 10 may be improved.

The semiconductor device 600 may be mounted on the second upper surface 230a of the chip redistribution wiring layer 230 and the upper substrate 500. Since the chip redistribution wiring layer 230 mounts the semiconductor device 600 on the second upper surface 230a, the mold gap between the first semiconductor chip 200 and the upper substrate 500 may be reduced. The first semiconductor chip 200 may directly transfer the heat generated from the activation layer 220 to the semiconductor device 600 through the chip redistribution wiring layer 230. Since the first semiconductor chip 200 is in the through cavity 550, the heat spreading effect may be improved.

Further, the chip redistribution wiring layer 230 of the first semiconductor chip 200 may be electrically insulated from the activation layer 220. The chip redistribution wiring layer 230 may be electrically connected to the semiconductor device 600 mounted on the upper substrate 500. Since the chip redistribution wiring layer 230 is electrically insulated from the activation layer 220, heat may not be generated within the chip redistribution wiring layer 230 and the chip redistribution wiring layer 230 may only absorb the heat from the activation layer 220 through the silicon substrate 210.

Hereinafter, a method of manufacturing the semiconductor package of FIG. 1 will be described.

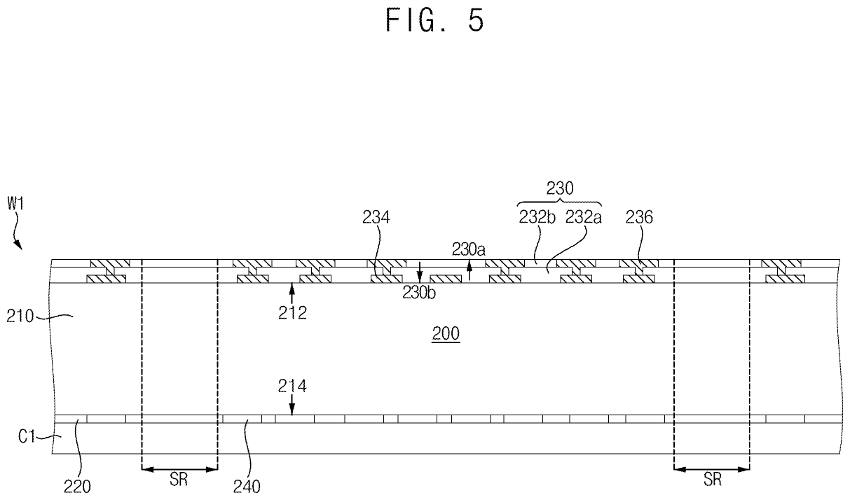

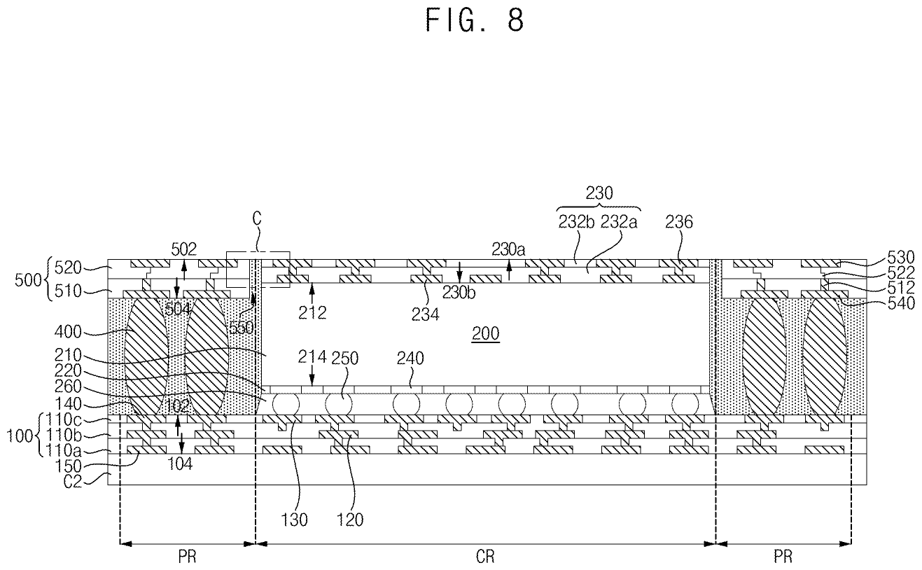

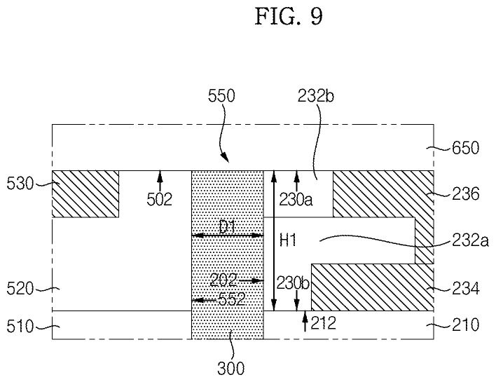

FIGS. 5 to 10 are views illustrating a method of manufacturing a semiconductor package in accordance with example embodiments.

Referring to FIG. 5, first, a chip redistribution wiring layer 230 may be formed on a silicon substrate 210 to provide a first semiconductor chip 200.

In example embodiments, a first semiconductor wafer W1 having a first surface 212 and a second surface 214 opposite to each other may be provided on a first carrier substrate C1. The first semiconductor wafer W1 may include the silicon substrate 210. An activation layer 220 may be formed on the second surface 214 of the first semiconductor wafer W1.

In particular, the silicon substrate 210 may be formed on the first carrier substrate C1 such that the activation layer 220 faces the first carrier substrate C1. Then, chip redistribution wirings 234 may be formed on the first surface 212 of the silicon substrate 210, and a first chip insulating layer 232a may be formed on the chip redistribution wirings 234. Then, the first chip insulating layer 232a may be patterned to form seventh openings that expose the chip redistribution wirings 234.

For example, the first chip insulating layer 232a may include a polymer, a dielectric layer, etc. In particular, the first chip insulating layer 232a may include polyimide (PI), lead oxide (PbO), polyhydroxystyrene (PHS), novolac (NOVOLAC), etc. The first chip insulating layer 232a may be formed by a vapor deposition process, a spin coating process, etc.

Then, chip redistribution pads 236 may be formed on the first chip insulating layer 232a to directly contact the chip redistribution wirings 234 through the seventh openings.

The chip redistribution pads 236 may be formed by forming a seed layer on a portion of the first chip insulating layer 232a and in the seventh openings, patterning the seed layer and performing an electrolytic plating process. Accordingly, at least portions of the chip redistribution pads 236 may directly contact the chip redistribution wirings 234 through the seventh openings.

For example, the chip redistribution wirings 234 and the chip redistribution pads 236 may include aluminum (Al), copper (Cu), tin (Sn), nickel (Ni), gold (Au), platinum (Pt), or an alloy thereof.

Then, a second chip insulating layer 232b may be formed on the first chip insulating layer 232a to cover or overlap the chip redistribution pads 236, and then, the second chip insulating layer 232b may be patterned to form eighth openings that expose the chip redistribution pads 236.

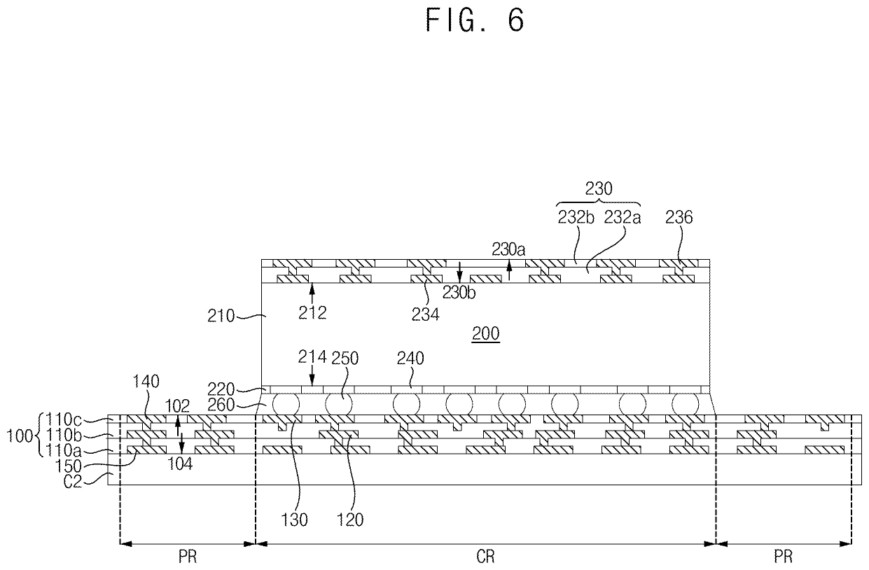

Referring to FIG. 6, first solder bumps 250 may be formed on first chip pads 240 of the activation layer 220, and the first semiconductor wafer W1 may be cut to form the first semiconductor chip 200. The first semiconductor wafer W1 may be cut along a scribe line region SR. The first semiconductor wafer W1 may be cut by a dicing process.

Then, a lower substrate 100 may be provided on a second carrier substrate C2, and the first semiconductor chip 200 may be mounted on the lower substrate 100.

In example embodiments, the lower substrate 100 may include a chip mounting region CR on which the first semiconductor chip 200 is mounted and a peripheral region PR at least partially surrounding the chip mounting region CR.

In particular, first connection pads 150 may be formed on the second carrier substrate C2, and a first insulating layer 110a may be formed on the first connection pads 150. Then, the first insulating layer 110a may be patterned to form first openings that expose the first connection pads 150.

For example, the first insulating layer 110a may include a polymer, a dielectric layer, etc. In particular, the first insulating layer 110a may include polyimide (PI), lead oxide (PbO), polyhydroxystyrene (PHS), novolac (NOVOLAC), etc. The first insulating layer 110a may be formed by a vapor deposition process, a spin coating process, etc.

Lower redistribution wirings 120 may be formed on the first insulating layer 110a to directly contact the first connection pads 150 through the first openings.

The lower redistribution wirings 120 may be formed by forming a seed layer on a portion of the first insulating layer 110a and in the first openings, patterning the seed layer and performing an electrolytic plating process. Accordingly, at least a portion of the lower redistribution wirings 120 may directly contact the first connection pads 150 through the first openings.

For example, the lower redistribution wirings 120 may include aluminum (Al), copper (Cu), tin (Sn), nickel (Ni), gold (Au), platinum (Pt), or an alloy thereof.

Then, a second insulating layer 110b may be formed on the first insulating layer 110a to cover or overlap the lower redistribution wirings 120, and the second insulating layer 110b may be patterned to form second openings that expose the lower redistribution wirings 120. First and second bonding pads 130 and 140 may be formed on the second insulating layer 110b to directly contact the lower redistribution wirings 120 through the second openings. The first bonding pads 130 may be formed in the chip mounting region CR and the second bonding pads 140 may be formed on the peripheral region PR.

Then, a third insulating layer 110c may be formed on the second insulating layer 110b to cover or overlap the first and second bonding pads 130 and 140, and the third insulating layer 110c may be patterned to form third openings that exposes the first and second bonding pads 130 and 140.

Then, the first semiconductor chip 200 may be mounted on the lower substrate 100.

In example embodiments, the first semiconductor chip 200 may be mounted on the lower substrate 100 using a flip chip bonding method. The first semiconductor chip 200 may be mounted on the chip mounting region CR of the lower substrate 100. The first chip pads 240 of the first semiconductor chip 200 may be electrically connected to the first bonding pads 130 of the lower substrate 100 via the first solder bumps 250. For example, the first solder bump 250 may include a micro bump (uBump).

A first adhesive member 260 may be underfilled between the lower substrate 100 and the first semiconductor chip 200. For example, the first adhesive member 260 may include an epoxy material to reinforce a gap between the lower substrate 100 and the first semiconductor chip 200.

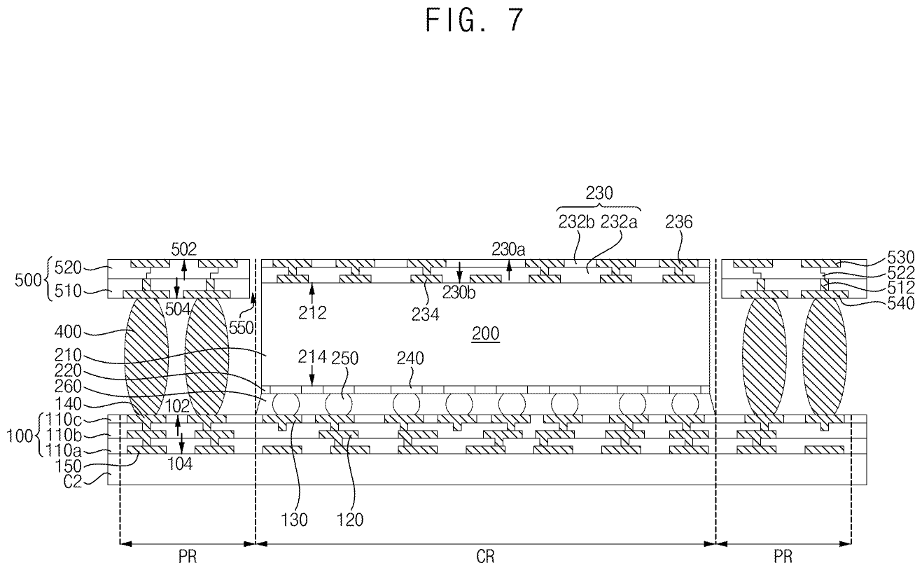

Referring to FIGS. 7 to 9, an upper substrate 500 may be mounted on the lower substrate 100 via connecting members 400. Alternatively, a plurality of the connecting members 400 may be formed on the second bonding pads 140 of the lower substrate 100, and the upper substrate 500 may be disposed on the connecting members 400.

In example embodiments, the upper substrate 500 may include a silicon interposer. The upper substrate 500 may have a through cavity 550 to accommodate at least a portion of the first semiconductor chip 200. The through cavity 550 may be provided on the chip mounting region CR of the lower substrate 100.

In example embodiments, the upper substrate 500 may be placed on the connecting members 400. The upper substrate 500 may be disposed on the connecting members 400 such that the first semiconductor chip 200 is accommodated in the through cavity 550. Alternatively, the upper substrate 500 may be placed on the lower substrate 100 via the connecting members 400 that are formed on a lower surface of the upper substrate 500.

For example, the connecting member 400 may be formed by a plating process, an electroless plating process, a vapor deposition process, etc. The connecting member 400 may have a pillar shape, a bump shape, etc.

The chip redistribution wiring layer 230 of the first semiconductor chip 200 may be accommodated in the through cavity 550. An outer surface 202 of the first semiconductor chip 200 may be spaced apart from an inner wall 552 of the through cavity 550. The inner wall 552 of the through cavity 550 and the outer surface 202 of the first semiconductor chip 200 may be spaced apart from each other by a first distance D1. For example, the first distance D1 may be within a range of about 1 mm to about 2 mm.

In example embodiments, a first sealing member 300 may be formed on the lower substrate 100 to cover or overlap the first semiconductor chip 200. The first sealing member 300 may cover or overlap the connecting members 400, the upper substrate 500, and the first semiconductor chip 200 on the lower substrate 100. The first sealing member 300 may be in the space between the inner wall 552 of the through cavity 550 and the outer surface 202 of the first semiconductor chip 200.

For example, the first sealing member 300 may include an epoxy mold compound (EMC). The first sealing member 300 may include UV resin, polyurethane resin, silicone resin, silica filler, etc.

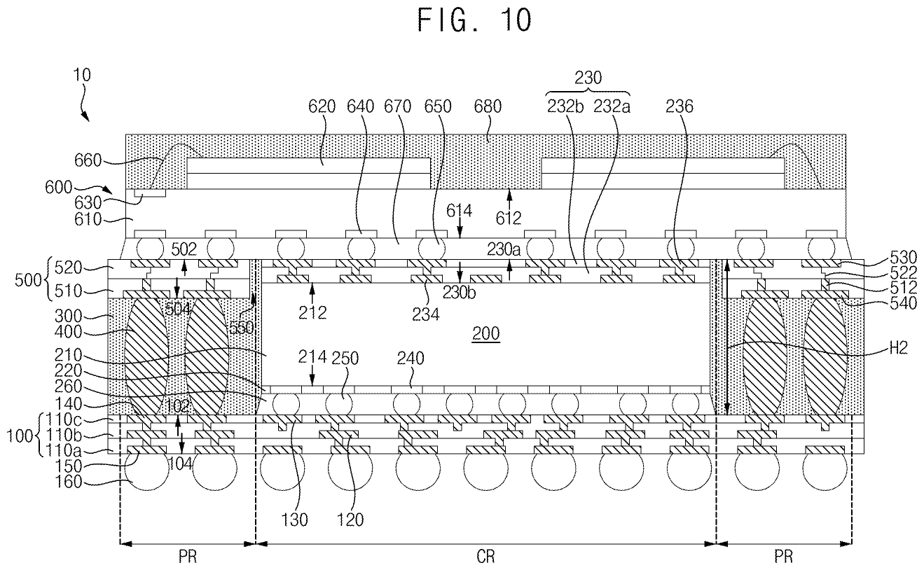

Referring to FIG. 10, processes the same as or similar to the processes described with reference to FIG. 6 may be performed to mount a semiconductor device 600 on the upper substrate 500, to complete the semiconductor package 10 of FIG. 1.

In example embodiments, second substrate pads 640 of the semiconductor device 600 may be electrically connected to third bonding pads 530 of the upper substrate 500 and the chip redistribution pads 236 of the chip redistribution wiring layer 230 by second solder bumps 650.

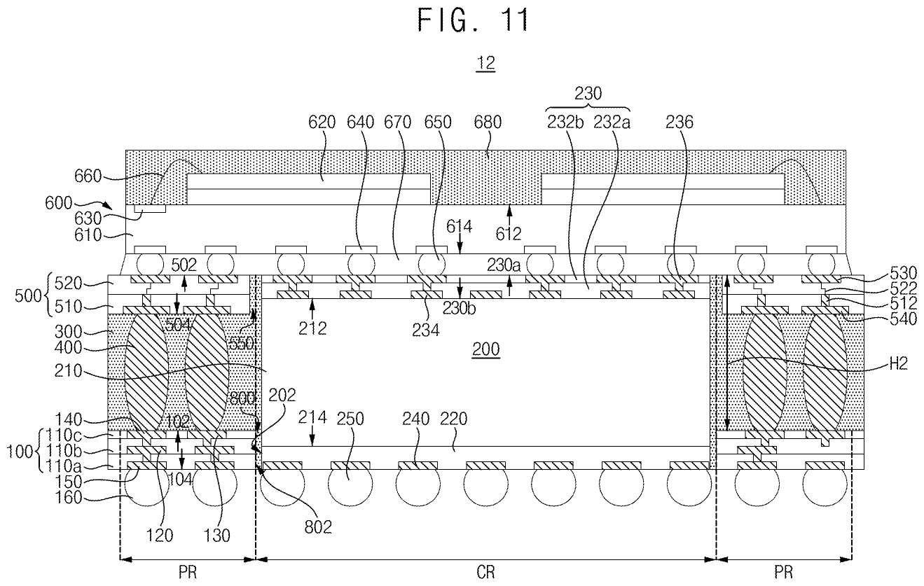

FIG. 11 is a cross-sectional view illustrating a semiconductor package in accordance with example embodiments. The semiconductor package may be substantially the same as the semiconductor package described with reference to FIGS. 1 to 4 except for a configuration of a lower substrate. Thus, same reference numerals may be used to refer to the same or like elements and any further repetitive explanation concerning the above elements will be omitted.

Referring to FIG. 11, a semiconductor package 12 may include a lower substrate 100, at least one first semiconductor chip 200 mounted on the lower substrate 100, a first sealing member 300 covering or overlapping the at least one first semiconductor chip 200 on the lower substrate 100, a plurality of connecting members 400 extending into the first sealing member 300 in a vertical direction, and an upper substrate 500 disposed on the first sealing member 300 and having a through cavity 550.

In example embodiments, the lower substrate 100 may have a second through cavity 800 to accommodate at least a portion of the first semiconductor chip 200. The second through cavity 800 may be provided in a chip mounting region CR of the lower substrate 100. The portion(s) of the first semiconductor chip 200 may be accommodated in the second through cavity 800. An activation layer 220 of the first semiconductor chip 200 may be accommodated in the second through cavity 800. The first sealing member 300 may be provided between a second inner wall 802 of the second through cavity 800 and an outer surface 202 of the first semiconductor chip 200.

The outer surface 202 of the first semiconductor chip 200 may be spaced apart from the second inner wall 802 of the second through cavity 800. Since the outer surface 202 of the first semiconductor chip 200 is spaced from the second inner wall 802 of the second through cavity 800, heat transfer between the lower substrate 100 and the first semiconductor chip 200 may be limited. Accordingly, heat generated from the activation layer 220 may be transferred to the silicon substrate 210.

Since the first semiconductor chip 200 is in the second through cavity 800, a thickness of the silicon substrate 210 of the first semiconductor chip 200 may increase. As the thickness of the silicon substrate 210 increases, a capacity of heat that the silicon substrate 210 can absorb from the activation layer 220 may increase, and an amount of heat dissipated from the first semiconductor chip 200 may increase.

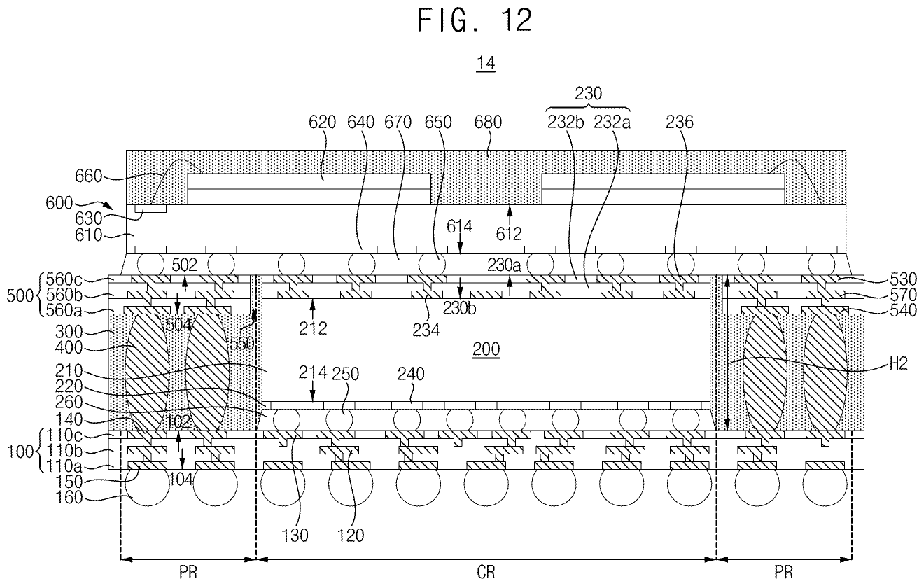

FIG. 12 is a cross-sectional view illustrating a semiconductor package in accordance with example embodiments. The semiconductor package may be substantially the same as the semiconductor package described with reference to FIGS. 1 to 4 except for a configuration of an upper substrate. Thus, same reference numerals may be used to refer to the same or like elements and any further repetitive explanation concerning the above elements will be omitted.

Referring to FIG. 12, an upper substrate 500 may include a redistribution wiring interposer. The upper substrate 500 may include a plurality of upper insulating layers 560a, 560b, 560c and upper wirings 570 provided in the upper insulating layers. Third bonding pads 530 and second connection pads 540 may be electrically connected to each other by the upper wirings 570.

In particular, a plurality of the third bonding pads 530 may be provided in a sixth insulating layer 560c (e.g., the uppermost insulating layer). Upper surfaces of the third bonding pads 530 may be exposed at an upper surface of the sixth insulating layer 560c (that is, a third upper surface 502 of the upper substrate 500). The sixth insulating layer 560c may have sixth openings that expose the upper surfaces of the third bonding pads 530.

A plurality of the second connection pads 540 may be provided in a fourth insulating layer 560a. Lower surfaces of the second connection pads 540 may be exposed at a lower surface of the fourth insulating layer 560a (that is, a third lower surface 504 of the upper substrate 500). The fourth insulating layer 560a may have fourth openings that expose upper surfaces of the second connection pads 540.

The upper wirings 570 may be formed on the fourth insulating layer 560a and may contact the second connection pads 540 through the fourth openings. The upper wirings 570 may be electrically connected to the connecting members 400. A fifth insulating layer 560b may be formed on the fourth insulating layer 560a and may have fifth openings that expose at least portions of the upper wirings 570.

The third bonding pads 530 may be formed on the fifth insulating layer 560b and may contact the upper wirings 570 through the fifth openings. The sixth insulating layer 560c may be formed on the fifth insulating layer 560b and may have the sixth openings that expose the third bonding pads 530. Accordingly, the plurality of third bonding pads 530 may be exposed at the upper surface of the sixth insulating layer 560c (that is, the third upper surface 502).

The semiconductor package may include semiconductor devices, such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices, such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A semiconductor package, comprising:
a lower substrate that comprises a chip mounting region and a peripheral region that at least partially surrounds the chip mounting region, wherein the lower substrate comprises lower redistribution wirings;
a first semiconductor chip on the chip mounting region, wherein the first semiconductor chip comprises:
a silicon substrate that comprises a first surface and a second surface that are opposite to each other,
an activation layer on the second surface, and
a chip redistribution wiring layer that is on the first surface and comprises a plurality of chip redistribution wirings that are electrically insulated from the activation layer;
a plurality of connecting members that are on the peripheral region and are electrically connected to the lower redistribution wirings; and
an upper substrate on the plurality of connecting members, wherein the upper substrate comprises upper wirings that are electrically connected to the plurality of connecting members, wherein the upper substrate defines a through cavity that is on the chip mounting region, and wherein at least a portion of the first semiconductor chip is in the through cavity.

2. The semiconductor package of claim 1, further comprising a sealing member that is on the lower substrate and overlaps an outer surface of the first semiconductor chip and an inner wall of the through cavity.

3. The semiconductor package of claim 1, wherein the lower substrate further defines a second through cavity, wherein at least a portion of the first semiconductor chip is in the second through cavity.

4. The semiconductor package of claim 1, further comprising a semiconductor device on the upper substrate and the first semiconductor chip, wherein the semiconductor device comprises a plurality of second semiconductor chips.

5. The semiconductor package of claim 4, wherein the upper wirings of the upper substrate and the chip redistribution wirings of the first semiconductor chip are electrically connected to each other by the semiconductor device.

6. The semiconductor package according to claim 1, wherein an outer surface of the first semiconductor chip and an inner wall of the through cavity are spaced apart from each other by a first distance.

7. The semiconductor package of claim 6, wherein the first distance is within a range of about 1 mm to about 2 mm.

8. The semiconductor package of claim 1, wherein the chip redistribution wiring layer of the first semiconductor chip extends from the first surface of the silicon substrate by a first height, and wherein the first height is within a range of about 25 μm to about 35 μm.

9. The semiconductor package of claim 1, wherein an upper surface of the chip redistribution wiring layer and an upper surface of the upper substrate are coplanar.

10. The semiconductor package of claim 9, wherein the upper surface of the chip redistribution wiring layer and the upper surface of the upper substrate extend from an upper surface of the lower substrate by a second height, and wherein the second height is within a range of about 180 μm to about 220 μm.

11. A semiconductor package, comprising:
a lower substrate that comprises a chip mounting region and a peripheral region that at least partially surrounds the chip mounting region, wherein the lower substrate comprises lower redistribution wirings;
a first semiconductor chip on the chip mounting region, wherein the first semiconductor chip comprises:
a silicon substrate that comprises a first surface and a second surface that are opposite to each other,
an activation layer on the second surface, and
a chip redistribution wiring layer that is on the first surface and comprises a plurality of chip redistribution wirings that are electrically insulated from the activation layer;
a sealing member that is on the lower substrate and overlaps an outer surface of the first semiconductor chip;
a plurality of connecting members that are on the peripheral region, wherein the plurality of connecting members extend into the sealing member and are electrically connected to the lower redistribution wirings; and
an upper substrate that is on the sealing member and comprises upper wirings, wherein the upper substrate is electrically connected to the plurality of connecting members by the upper wirings, and wherein the upper substrate defines a through cavity that is on the chip mounting region and receives at least a portion of the first semiconductor chip.

12. The semiconductor package of claim 11, wherein the sealing member overlaps an inner wall of the through cavity.

13. The semiconductor package of claim 11, further comprising a semiconductor device on the upper substrate and the first semiconductor chip, wherein the semiconductor device comprises a plurality of second semiconductor chips.

14. The semiconductor package of claim 13, wherein the upper wirings of the upper substrate and the chip redistribution wirings of the first semiconductor chip are electrically connected to each other by the semiconductor device.

15. The semiconductor package of claim 11, wherein the outer surface of the first semiconductor chip and an inner wall of the through cavity are spaced apart from each other by a first distance.

16. The semiconductor package of claim 15, wherein the first distance is within a range of about 1 mm to about 2 mm.

17. The semiconductor package of claim 11, wherein the chip redistribution wiring layer of the first semiconductor chip extends from the first surface by a first height, and wherein the first height is within a range of about 25 μm to about 35 μm.

18. The semiconductor package of claim 11, wherein an upper surface of the chip redistribution wiring layer and an upper surface of the upper substrate are coplanar.

19. The semiconductor package of claim 18, wherein the upper surface of the chip redistribution wiring layer and the upper surface of the upper substrate extend from an upper surface of the lower substrate by a second height, and wherein the second height is within a range of about 180 μm to about 220 μm.

20. A semiconductor package, comprising:
a lower substrate that comprises a chip mounting region and a peripheral region that at least partially surrounds the chip mounting region, wherein the lower substrate comprises lower redistribution wirings;
a first semiconductor chip on the chip mounting region, wherein the first semiconductor chip comprises:
a silicon substrate that comprises a first surface and a second surface that are opposite to each other,
an activation layer that is on the second surface and is electrically connected to the lower redistribution wirings, and
a chip redistribution wiring layer that is on the first surface and comprises a plurality of chip redistribution wirings that are electrically insulated from the activation layer;
a sealing member that is on the lower substrate and overlaps an outer surface of the first semiconductor chip;
a plurality of connecting members that are on the peripheral region, wherein the plurality of connecting members extend into the sealing member and are electrically connected to the lower redistribution wirings;
an upper substrate that is on the sealing member and comprises upper wirings, wherein the upper substrate is electrically connected to the plurality of connecting members by the upper wirings, wherein the upper substrate defines a through cavity that is on the chip mounting region, and wherein least a portion of the first semiconductor chip is in the through cavity; and
a semiconductor device that is on the upper substrate and is electrically connected to the upper wirings of the upper substrate and the chip redistribution wirings of the first semiconductor chip.
